(19) United States
(12) Patent Application Publication
(10) Pub. No.: US 2025/0259956 A1
(43) Pub. Date: Aug. 14, 2025

(54) STACKED DIE STRUCTURE

(71) Applicant: QUALCOMM Incorporated, San Diego, CA (US)

(72) Inventors: Yangyang SUN, San Diego, CA (US); Aniket PATIL, San Diego, CA (US); Nader NIKFAR, San Diego, CA (US)

(21) Appl. No.: 18/438,419

(22) Filed: Feb. 10, 2024

(51) Int. Cl. H01L 23/00; H01L 25/00; H01L 25/065; H01L 25/18; H10B 80/00

(52) U.S. Cl. CPC H01L 24/20; H01L 24/05; H01L 24/08; H01L 24/16; H01L 24/19; H01L 24/32; H01L 24/73; H01L 25/50; H01L 25/0657; H01L 25/18; H01L 2224/05647; H01L 2224/08225; H01L 2224/16227; H01L 2224/19; H01L 2224/211; H01L 2224/215; H01L 2224/32225; H01L 2224/73204; H01L 2225/06524; H01L 2225/06548; H01L 2924/01029; H10B 80/00

(57) ABSTRACT

In an aspect, an IC device may include a structure wafer and a first die bonded to the structure wafer by a bonding layer. A first metallization structure is disposed below and electrically coupled to the first die opposite the structure wafer. A fill material is disposed between the structure wafer and the first metallization structure. A second metallization structure is disposed on top of the structure wafer. The second metallization structure includes a second plurality of inorganic dielectric layers. A second die is disposed on top of the second metallization structure and electrically coupled to the second metallization structure by a plurality of die connectors. A plurality of through-substrate vias electrically couple the first metallization structure to the second metallization structure.

### TECHNICAL FIELD

The present disclosure generally relates to semiconductor devices including an integrated circuit (IC) package, and more particularly, but not exclusively, to devices including a stacked die structure and fabrication techniques thereof.

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a packaging substrate for packaging one or more IC chips into an IC package, which is different from the semiconductor substrate for forming an IC chip.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth™, and other communications), and the like. As used herein the term “function block” should not be construed to be power or signal lines, traces, conductors, pads, etc. that merely function to transmit an electrical voltage and/or current.

As designs become more complex, demands increase on the package substrate design and packaging technology. In conventional packaging technology, package on package (PoP) devices have evolved in order to reduce Z-height and increase POP connection density to accommodate more complex IC devices (e.g., larger memory, more processors, more active circuits, etc.). However, conventional polymer/copper (Cu) redistribution layer (RDL) based fan-out packages have limitations due to thermal performance and warpage page control. Additionally, dynamic random-access memory (DRAM), double data rate (DDR) memory (e.g., DDR6) and future DRAM to processor connections (e.g., an application processor (AP) to DDR6) connections also have connection bottlenecks due to pitch and routing limitation with current RDL or organic interposer technology.

Accordingly, there is a need for improved IC design, IC packaging and methods of manufacturing the same to address the above-noted issues in the conventional technology and other improvements, as disclosed herein.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In some aspects, the apparatus comprises a structure wafer; a first die bonded to the structure wafer by a bonding layer; a first metallization structure disposed below and electrically coupled to the first die opposite the structure wafer; fill material disposed between the structure wafer and the first metallization structure, wherein the fill material embeds the first die; a second metallization structure disposed on top of the structure wafer, wherein the second metallization structure includes a second plurality of inorganic dielectric layers; a second die disposed on top of the second metallization structure and electrically coupled to the second metallization structure by a plurality of die connectors; and a plurality of through-substrate vias configured to electrically couple the first metallization structure to the second metallization structure.

In some aspects, the techniques described herein relate to a method of manufacturing an apparatus, the method comprising: providing a structure wafer; attaching a first die to the structure wafer by a bonding layer; forming a first metallization structure including electrically coupling the first metallization structure to the first die, wherein the first metallization structure is disposed below the first die opposite the structure wafer; depositing a fill material between the structure wafer and the first metallization structure, wherein the fill material embeds the first die; forming a second metallization structure disposed on top of the structure wafer, wherein the second metallization structure includes a second plurality of inorganic dielectric layers; attaching a second die including electrically coupling the second die to the second metallization structure by a plurality of die connectors, wherein the second die is disposed on top of the second metallization structure; and forming a plurality of through-substrate vias configured to electrically couple the first metallization structure to the second metallization structure.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 includes partial cross-sectional views of apparatus including an integrated circuit (IC) package, according to aspects of the disclosure.

FIGS. 2A-2I illustrate structures at various stages of manufacturing a substrate for an IC package, according to aspects of the disclosure.

FIG. 3 illustrates partial cross-sectional views of apparatus including an integrated circuit (IC) package, according to aspects of the disclosure.

FIG. 4 illustrates partial cross-sectional views of apparatus including an integrated circuit (IC) package, according to aspects of the disclosure.

FIG. 5 illustrates partial cross-sectional views of apparatus including an integrated circuit (IC) package, according to aspects of the disclosure.

FIG. 6 illustrates a method for manufacturing a substrate for an IC package, according to aspects of the disclosure.

FIG. 7 illustrates a mobile device, according to aspects of the disclosure.

FIG. 8 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, substantially and the like indicate that the examples provided are not intended to be limited to the precise numerical values or geometric shapes and include normal variations due to, manufacturing tolerances and variations, material variations, and other design considerations.

As noted in the foregoing, conventional technologies including conventional packaging technology including POP devices have design limitations. For example, conventional polymer/Cu RDL based fan-out packages have limitations due to thermal performance and warpage page control. Additionally, high density connections, such as AP to DDR6 connections have connection bottlenecks due to pitch and routing limitations in conventional RDL or organic interposer technology. The various aspects disclosed provide improvements including new fabrication processes to form the metallization structures (e.g., RDL layers) for stacked die structures comprising silicon or inorganic dielectric layers, which provide for higher density connections. In some aspects, a metal damascene process (e.g., Cu damascene process) is used to build-up the various layers of the metallization structures and provide for fine pitch and a fully integrated fabrication process. The inorganic materials provide for improved thermal performance as the inorganic dielectric material is ten or more times greater than conventional organic dielectric material. For example, an inorganic dielectric material, such as silicon (Si), has thermal conductivity (W/mK) of 150 and an organic dielectric material, such as fluorinated tetraethyl orthosilicate (FTEOS), has thermal conductivity (W/mK) of 12. It will be appreciated that the various stacked die structures disclosed provide improved mechanical, thermal and electrical performance. The various stacked die structures disclosed allow for various configurations. For example, some aspects, the stacked die structure may include a first metallization structure comprising organic dielectric layers, which is coupled to an embedded die (e.g., processor, etc.) and a second metallization structure comprising inorganic dielectric layers coupled to a top die (e.g., memory, DDRAM, etc.). The term “metallization structure” as used herein may include any configuration of metal layers, vias and dielectric layers. In some aspects, a metallization structure may function as a redistribution layer (RDL) structure, which may provide for metal interconnects that redistribute the access to different parts of the die and in some aspects may allow for a change in pitch between connectors to allow for easier connection from the die to external components. It will be appreciated that the various aspects disclosed are not limited to these advantages and configurations and additional advantages and configurations are disclosed in the following description.

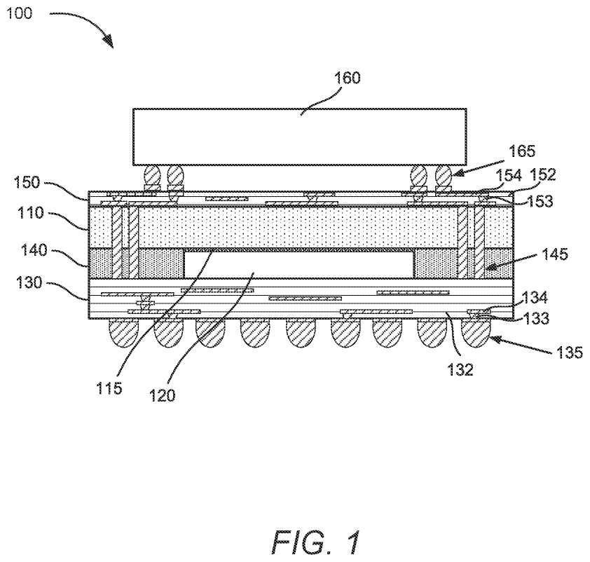

FIG. 1 is a cross-sectional view of an apparatus 100, according to aspects of the disclosure. In some aspects, FIG. 1 is a simplified cross-sectional view of the apparatus 100, and certain details and components of the apparatus 100 may be simplified or omitted in FIG. 1.

In some aspects, as shown in FIG. 1, the apparatus 100 is illustrated as a portion of an IC package and/or a larger apparatus such as a mobile phone, etc. In some aspects, the apparatus 100 includes a structure wafer 110 (e.g., a dummy Si wafer, or glass wafer) and a first die 120 (e.g., a processor die, AP die, etc.) bonded to the structure wafer 110 by a bonding layer 115 (e.g., oxide bonding or similar bonding techniques). A first metallization structure 130 is disposed below and electrically coupled to the first die 120 opposite the structure wafer 110. The first die 120 and the first metallization structure 130 can be electrically coupled using any conventional technology. For example, in some aspects, the first metallization structure 130 may contact with first die 120 internal metal layers thru passivation openings, similar as back end of line (BEOL) or wafer level redistribution layer RDL processing. For convenience of illustration the connections/connectors are not illustrated. The first metallization structure 130 comprises a first plurality of inorganic dielectric layers 132. A fill material 140 is disposed between the structure wafer 110 and the first metallization structure 130. The fill material 140 embeds the first die 120. The fill material may comprise an oxide material. A second metallization structure 150 is disposed on top of the structure wafer 110. The second metallization structure 150 comprises a second plurality of inorganic dielectric layers 152. A second die 160 (e.g., memory, DRAM, DDR6, processor or other active component) is disposed on top of the second metallization structure 150 and electrically coupled to the second metallization structure 150 by a plurality of die connectors 165 (e.g., die bumps, solder, pins, pillars, or any suitable connector design). It will be appreciated that the various aspects disclosed and claimed are not limited to the illustrated examples. For example, one or more additional dies may be coupled to first metallization structure 130 and/or the second metallization structure 150. Further, in some aspects, one or more additional dies may be coupled to the second die 160 in a stacked configuration. Still further, additional stacked die configurations will be discussed in the following paragraphs.

In some aspects, the first metallization structure 130 includes a plurality of inorganic dielectric layers 132, a plurality of metal layers 134 disposed in the first plurality of inorganic dielectric layers 132 and a plurality of vias 133 coupling adjacent metal layers 134 of the plurality of metal layers 134 through the first plurality of inorganic dielectric layers 132. In some aspects, the second metallization structure 150 includes a second plurality of inorganic dielectric layers 152, a plurality of metal layers 154 disposed in the second plurality of inorganic dielectric layers 152 and a plurality of vias 153 coupling adjacent metal layers 154 of the plurality of metal layers 154 through the second plurality of inorganic dielectric layers 152. In some aspects the first and second plurality of inorganic dielectric layers may comprise silicon (Si), gallium arsenide (GaAs), silicon germanium (SiGe), silicon oxide, silicon nitride and similar inorganic materials.

A plurality of through-substrate vias (TSVs) 145 are configured to electrically couple the first metallization structure 130 to the second metallization structure 150. The plurality of TSVs 145 traverses the fill material 140 and structure wafer 110 and are disposed outside the first die 120. A plurality of package connectors 135 (e.g., solder balls, ball grid array (BGA), copper pillars, bumps, pins or any suitable connector technology) may be configured to electrically couple the apparatus 100 to an external component, such as a circuit board.

In some aspects, the first metallization structure 130 may comprise multiple layers of silicon or other inorganic based build-up layers. In some aspects, the second metallization structure 150 may comprise multiple layers of silicon or other inorganic based build-up layers. In some aspects, the metal layers and vias of the first metallization structure 130, the second metallization structure 150 and TSVs 145 may comprise any high conductive material, such as, copper (Cu), aluminum (AL), silver (Ag), gold (Au) titanium (Ti), nickel (Ni), tin (Sn), lead (Pb), alloys or combinations thereof.

It will be appreciated that the illustrated configurations and descriptions provided herein are merely to aid in the explanation of the various aspects disclosed herein. Accordingly, the forgoing illustrative examples should not be construed to limit the various aspects disclosed and claimed herein.

In order to fully illustrate aspects of the design of the present disclosure, methods of fabrication are presented. Further, many details in the fabrication process known to those skilled in the art may have been omitted or combined in summary process portions to facilitate an understanding of the various aspects disclosed without a detailed rendition of each detail and/or all possible process variations. Other methods of fabrication are possible, and discussed fabrication methods are presented only to aid understanding of the concepts disclosed herein.

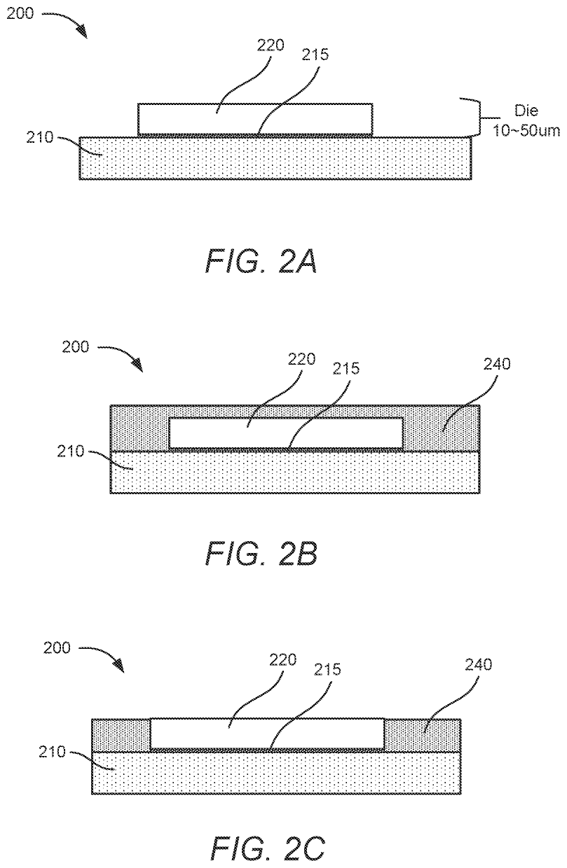

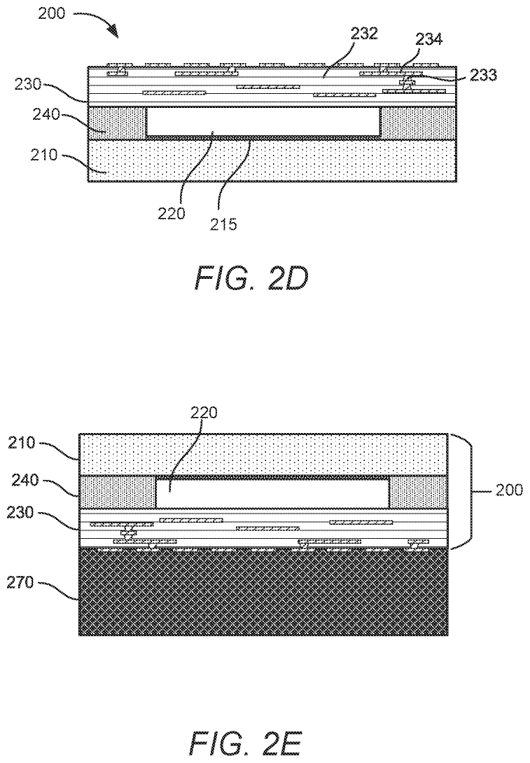

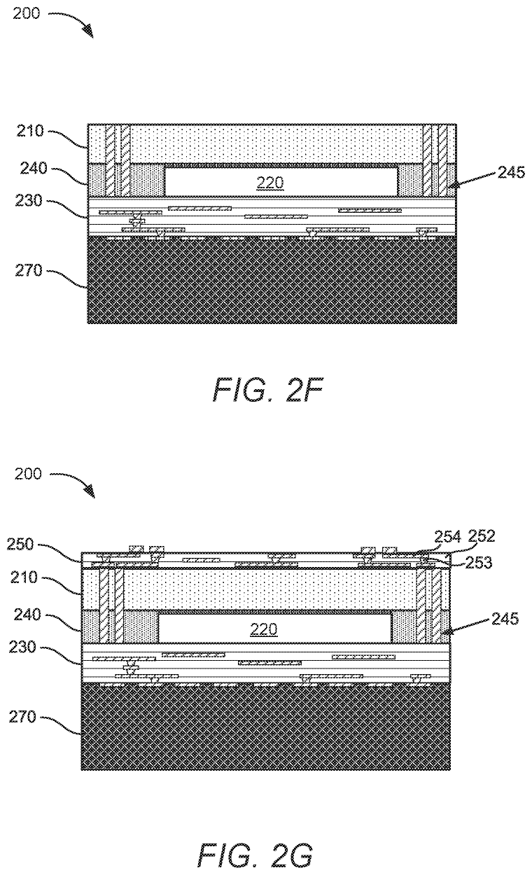

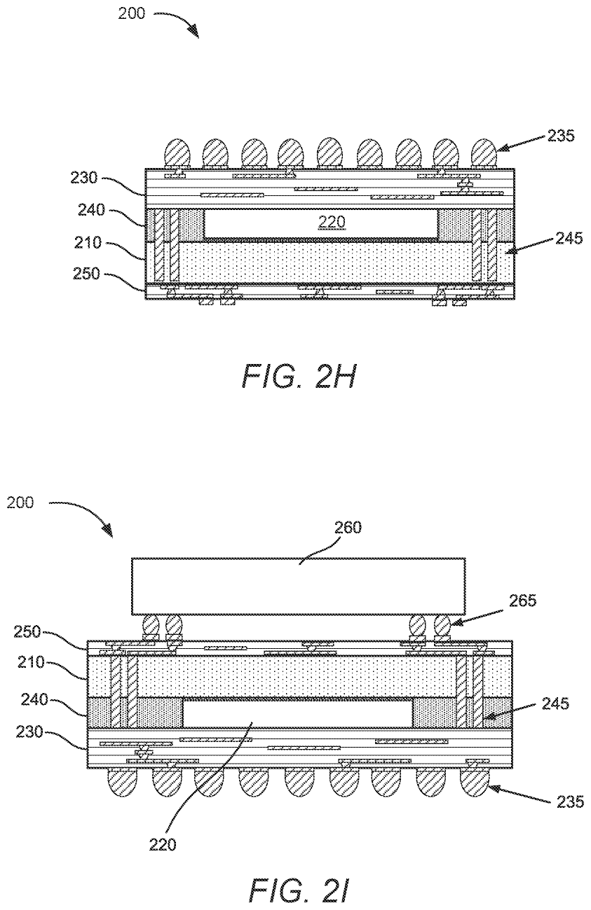

FIGS. 2A-2I illustrate structures at various stages of manufacturing/fabricating an apparatus 200, which is similar to the example apparatus 100 in FIG. 1 as a non-limiting example, according to aspects of the disclosure. Many of the elements illustrated in FIGS. 2A-2I are the same or similar to those of FIG. 1, and therefore detailed description thereof may be omitted.

As shown in FIG. 2A, the fabrication process for apparatus 200 may begin with a structure wafer 210 (e.g., a dummy Si wafer) with a first die 220 being bonded to the structure wafer 210 by bonding layer 215. The bonding may be performed by a fusion bonding process or any conventional die bonding process.

In FIG. 2B, the fabrication process for apparatus 200 may continue with the first die 220 being bonded to the structure wafer 210 by bonding layer 215. At this stage of the fabrication process, a fill material 240 may be deposited over the first die 220 and the structure wafer 210. The fill material 240 at this stage extends over the top of the first die 220. In some aspects, the fill material 240 may be a deposited by a spin coating process and may be a spin-on dielectric oxide.

In FIG. 2C, the fabrication process for apparatus 200 may continue with the first die 220 being bonded to the structure wafer 210 by bonding layer 215 overlayed with the fill material 240. At this stage of the fabrication process, a planarization process is performed to expose the first die 220, with the exposed surface of the first die 220 being planar with a top surface of the fill material. In some aspects, the planarization process may be performed by a chemical mechanical polishing (CMP) process or any other conventional planarization process.

In FIG. 2D, the fabrication process for apparatus 200 may continue with the first die 220, the structure wafer 210, the bonding layer 215 and the fill material 240, as previously described. At this stage of the fabrication process, a first metallization structure 230 is formed. In some aspects, the first metallization structure 230 may be formed from a plurality of inorganic dielectric layers and metal layers being formed by a metal damascene process (e.g., copper (Cu) damascene process), which may be a single or dual damascene process. In some aspects, the first metallization structure 230 may be formed by plated Cu with deposited passivation layer. In some aspects, the first metallization structure 230 comprises a first plurality of inorganic dielectric layers 232, a plurality of metal layers 234 disposed in the first plurality of inorganic dielectric layers 232 and a plurality of vias 233 coupling adjacent metal layers 234 of the plurality of metal layers 234 through the first plurality of inorganic dielectric layers 232. The fill material 240 is disposed between the structure wafer 210 and the first metallization structure 230 and encapsulates the first die 220.

In FIG. 2E, the fabrication process for apparatus 200 may continue with the first die 220, the structure wafer 210, the bonding layer 215, the fill material 240, and the first metallization structure 230, as previously described. At this stage of the fabrication process, the partially formed apparatus 200 is flipped and a carrier wafer 270 is bonded to the first metallization structure 230 to provide support and allow for further processing.

In FIG. 2F, the fabrication process for apparatus 200 may continue with the first die 220, the structure wafer 210, the bonding layer 215, the fill material 240, and the first metallization structure 230 attached to the carrier wafer 270, as previously described. At this stage of the fabrication process, the structured wafer 210 can be thinned to a desired thickness, based on specific design and thermal considerations, which will impact the Z-height of the final product. In some aspects, the structured wafer 210 can be thinned to a range of 150 um to 250 um. Additionally, a plurality of through-substrate vias (TSVs) 245 are formed and electrically coupled to the first metallization structure 230. The plurality of TSVs 245 traverses the fill material 240 and structure wafer 210 and are planar with the thinned surface structured wafer 210. In some aspects, the TSVs 245 are disposed outside the first die 220. The TSVs 245 may be formed by etching to form the openings, which allows for a fine pitch of the TSVs 245 and then filled with copper (e.g., copper plating) or other conductive material. In some aspects, the pitch of the TSVs 245 are in the range of 10 um to 200 um. In some aspects, the TSVs 245 may be formed by an etching process (dry or wet), laser drilling, or other conventional techniques.

In FIG. 2G, the fabrication process for apparatus 200 may continue with the first die 220, the structure wafer 210, the bonding layer 215, the fill material 240, the first metallization structure 230 attached to the carrier wafer 270, and TSVs 245, as previously described. At this stage of the fabrication process, a second metallization structure 250 is formed disposed on the structure wafer 210. In some aspects, the second metallization structure 250 may be formed from a plurality of inorganic dielectric layers and metal layers being formed by a copper damascene process. In some aspects, the second metallization structure 250 comprises a second plurality of inorganic dielectric layers 252, a plurality of metal layers 254 disposed in the second plurality of inorganic dielectric layers 252 and a plurality of vias 253 coupling adjacent metal layers 254 of the plurality of metal layers 254 through the second plurality of inorganic dielectric layers 252. It will be appreciated that the second metallization structure 250 is electrically coupled to the TSVs 245 which allows for an electrical connection between the first metallization structure 230 and the second metallization structure 250. Further, it will be appreciated that using copper damascene processes and inorganic dielectric layers to form the first metallization structure 230 and the second metallization structure 250 allows for finer pitch and improved routing.

In FIG. 2H, the fabrication process for apparatus 200 may continue with the first die 220, the structure wafer 210, the bonding layer 215, the fill material 240, the first metallization structure 230, TSVs 245 and the second metallization structure 250, as previously described. At this stage of the fabrication process, the carrier wafer 270 is detached (e.g., debonding process) from the first metallization structure 230. The partially formed apparatus 200 is flipped. A plurality of package connectors 235 (e.g., solder bumps, BGA, copper pillar bumps, pins or any suitable connector technology), coupled to the first metallization structure, are formed (e.g., ball-drop on pads of the first metallization structure 230 or any conventional process). The plurality of package connectors 235 can be configured to couple to an external component, such as a circuit board. Accordingly, it will be appreciated that the package connectors may vary depending on the device design.

In FIG. 2I, the fabrication process for apparatus 200 may continue with the first die 220, the structure wafer 210, the bonding layer 215, the fill material 240, the first metallization structure 230, TSVs 245, the second metallization structure 250 and package connectors 235, as previously described. At this stage of the fabrication process. The partially formed apparatus 200 is flipped so that the second metallization structure 250 is exposed on the top. A second die 260 is coupled to the second metallization structure 250 by a plurality of die connectors 265 (e.g., die bumps, solder, pins, pillars, or any suitable connector design) using conventional processes for a given connector technology. It will be appreciated at this stage the apparatus 200 is similarly configured as apparatus 100, described above. Accordingly, details of each element will not be further provided.

It will be appreciated that additional processing can be performed using known techniques to form and attach additional structures (e.g., a mold compound, lid, etc. may be used to encapsulate the stacked die structure). Additional dies may be coupled to the stacked die structure or arranged in a further stacked structure. Further, the various aspects disclosed may include additional substrates that may be used to interface to a printed circuit board (PCB) or other external device. Accordingly, it will be appreciated that the various aspects disclosed are not limited to the specific configurations illustrated in the accompanying figures.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

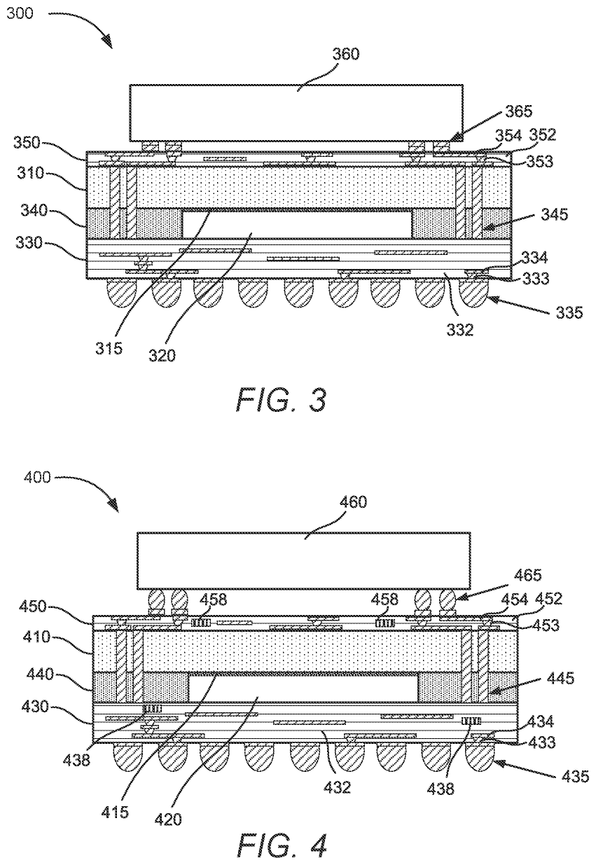

FIG. 3 is a cross-sectional view of an apparatus 300, according to aspects of the disclosure. In some aspects, FIG. 3 is a simplified cross-sectional view of the apparatus 300 and certain details and components of the apparatus 300 may be simplified or omitted in FIG. 3.

In some aspects, as shown in FIG. 3, the apparatus 300 is illustrated as a portion of an IC package and/or a larger apparatus such as a mobile phone, etc. In some aspects, the apparatus 300 includes a structure wafer 310 and a first die 320 bonded to the structure wafer 310 by a bonding layer 315. A first metallization structure 330 is disposed below and electrically coupled to the first die 320 opposite the structure wafer 310. The first die 320 and the first metallization structure 330 can be electrically coupled using any conventional technology, and for convenience of illustration the connections/connectors are not illustrated. In some aspects, the first metallization structure 330 comprises a first plurality of inorganic dielectric layers 332. A fill material 340 is disposed between the structure wafer 310 and the first metallization structure 330. The fill material 340 embeds the first die 320. A second metallization structure 350 is disposed on top of the structure wafer 310. The second metallization structure 350 comprises a second plurality of inorganic dielectric layers 352. A second die 360 is disposed on top of the second metallization structure 350 and electrically coupled to the second metallization structure 350 by a plurality of die connectors 365. In the illustrated aspect, it will be appreciated that the plurality of die connectors 365 may be hybrid bonded contacts formed by a copper-to-copper hybrid bonding process of the second die 360 to the second metallization structure 350.

In some aspects, the first metallization structure 330 includes a plurality of inorganic dielectric layers 332, a plurality of metal layers 334 disposed in the first plurality of inorganic dielectric layers 332 and a plurality of vias 333 coupling adjacent metal layers 334 of the plurality of metal layers 334 through the first plurality of inorganic dielectric layers 332. In some aspects, the second metallization structure 350 includes a second plurality of inorganic dielectric layers 352, a plurality of metal layers 354 disposed in the second plurality of inorganic dielectric layers 352 and a plurality of vias 353 coupling adjacent metal layers 354 of the plurality of metal layers 354 through the second plurality of inorganic dielectric layers 352. In some aspects the first and second plurality of inorganic dielectric layers may comprise silicon (Si), gallium arsenide (GaAs), silicon germanium (SiGe) and similar inorganic materials.

A plurality of through-substrate vias (TSVs) 345 are configured to electrically couple the first metallization structure 330 to the second metallization structure 350. The plurality of TSVs 345 traverses the fill material 340 and structure wafer 310 and are disposed outside the first die 320. A plurality of package connectors 335 (e.g., solder bumps, BGA, copper pillar bumps, pins or any suitable connector technology) may be configured to electrically couple the apparatus 300 to an external component, such as a circuit board.

In some aspects, the first metallization structure 330 may comprise multiple layers of silicon or other inorganic based build-up layers. In some aspects, the second metallization structure 350 may comprise multiple layers of silicon or other inorganic based build-up layers as part of a copper damascene process. In some aspects, the metal layers and vias of the first metallization structure 330, the second metallization structure 350 and TSVs 345 may comprise any high conductive material, such as, copper (Cu), aluminum (AL), silver (Ag), gold (Au) titanium (Ti), nickel (Ni), tin (Sn), lead (Pb), alloys or combinations thereof.

It will be appreciated that the illustrated configurations and descriptions provided herein are merely to aid in the explanation of the various aspects disclosed herein. Accordingly, the forgoing illustrative examples should not be construed to limit the various aspects disclosed and claimed herein.

FIG. 4 is a cross-sectional view of an apparatus 400, according to aspects of the disclosure. In some aspects, FIG. 4 is a simplified cross-sectional view of the apparatus 400 and certain details and components of the apparatus 400 may be simplified or omitted in FIG. 4.

In some aspects, as shown in FIG. 4, the apparatus 400 is illustrated as a portion of an IC package and/or a larger apparatus such as a mobile phone, etc. In some aspects, the apparatus 400 includes a structure wafer 410 and a first die 420 bonded to the structure wafer 410 by a bonding layer 415. A first metallization structure 430 is disposed below and electrically coupled to the first die 420 opposite the structure wafer 410. The first die 420 and the first metallization structure 430 can be electrically coupled using any conventional technology, and for convenience of illustration the connections/connectors are not illustrated. In some aspects, the first metallization structure 430 comprises a first plurality of inorganic dielectric layers 432. A fill material 440 is disposed between the structure wafer 410 and the first metallization structure 430. The fill material 440 embeds the first die 420. A second metallization structure 450 is disposed on top of the structure wafer 410. The second metallization structure 450 comprises a second plurality of inorganic dielectric layers 452. A second die 460 is disposed on top of the second metallization structure 450 and electrically coupled to the second metallization structure 450 by a plurality of die connectors 465.

In some aspects, the first metallization structure 430 includes a plurality of inorganic dielectric layers 432, a plurality of metal layers 434 disposed in the first plurality of inorganic dielectric layers 432 and a plurality of vias 433 coupling adjacent metal layers 434 of the plurality of metal layers 434 through the first plurality of inorganic dielectric layers 432. In some aspects the first metallization structure 430 may include one or more integrated passive devices 438. In some aspects, the one or more integrated passive devices 438 may be a capacitor and/or an inductor. In some aspects, the one or more integrated passive devices may be a metal-insulator-metal (MIM) capacitor, which may be formed during the same processing (Cu damascene processing) that forms the first metallization structure 430.

In some aspects, the second metallization structure 450 includes a second plurality of inorganic dielectric layers 452, a plurality of metal layers 454 disposed in the second plurality of inorganic dielectric layers 452 and a plurality of vias 453 coupling adjacent metal layers 454 of the plurality of metal layers 454 through the second plurality of inorganic dielectric layers 452. In some aspects the second metallization structure 450 may include one or more integrated passive devices 458. In some aspects, the one or more integrated passive devices 458 may be a capacitor and/or an inductor. In some aspects, the one or more integrated passive devices 458 may be a metal-insulator-metal (MIM) capacitor, which may be formed during the same processing (Cu damascene processing) that forms the second metallization structure 450.

A plurality of through-substrate vias (TSVs) 445 are configured to electrically couple the first metallization structure 430 to the second metallization structure 450. The plurality of TSVs 445 traverses the fill material 440 and structure wafer 410 and are disposed outside the first die 420. A plurality of package connectors 435 (e.g., solder bumps, BGA, copper pillar bumps, pins or any suitable connector technology) may be configured to electrically couple the apparatus 400 to an external component, such as a circuit board.

In some aspects, the first metallization structure 430 may comprise multiple layers of silicon or other inorganic based build-up layers. In some aspects, the second metallization structure 450 may comprise multiple layers of silicon or other inorganic based build-up layers as part of a copper (Cu) damascene process. In some aspects, the metal layers and vias of the first metallization structure 430, the second metallization structure 450 and TSVs 445 may comprise any high conductive material, such as, copper (Cu), aluminum (AL), silver (Ag), gold (Au) titanium (Ti), nickel (Ni), tin (Sn), lead (Pb), alloys or combinations thereof.

It will be appreciated that the illustrated configurations and descriptions provided herein are merely to aid in the explanation of the various aspects disclosed herein. Accordingly, the forgoing illustrative examples should not be construed to limit the various aspects disclosed and claimed herein.

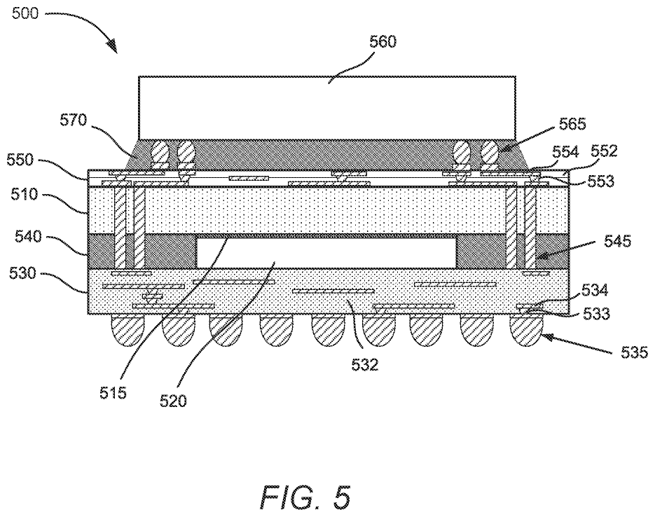

FIG. 5 is a cross-sectional view of an apparatus 500, according to aspects of the disclosure. In some aspects, FIG. 5 is a simplified cross-sectional view of the apparatus 500 and certain details and components of the apparatus 500 may be simplified or omitted in FIG. 5.

In some aspects, as shown in FIG. 5, the apparatus 500 is illustrated as a portion of an IC package and/or a larger apparatus such as a mobile phone, etc. In some aspects, the apparatus 500 includes a structure wafer 510 and a first die 520 bonded to the structure wafer 510 by a bonding layer 515. A first metallization structure 530 is disposed below and electrically coupled to the first die 520 opposite the structure wafer 510. The first die 520 and the first metallization structure 530 can be electrically coupled using any conventional technology, and for convenience of illustration the connections/connectors are not illustrated. In some aspects, the first metallization structure 530 comprises a first plurality of inorganic dielectric layers 532. A fill material 540 is disposed between the structure wafer 510 and the first metallization structure 530. The fill material 540 embeds the first die 520. In some aspects, the fill material 540 may be an organic material (e.g., underfill, polyimide and the like). A second metallization structure 550 is disposed on top of the structure wafer 510. The second metallization structure 550 comprises a second plurality of inorganic dielectric layers 552. A second die 560 is disposed on top of the second metallization structure 550 and electrically coupled to the second metallization structure 550 by a plurality of die connectors 565. In some aspects, a die underfill material 570 may be disposed between the second die 560 and the second metallization structure 550 and encapsulate the die connectors 565. In some aspects, the die underfill material 570 comprise an organic material.

In some aspects, the first metallization structure 530 includes a plurality of organic dielectric layers 532, a plurality of metal layers 534 disposed in the first plurality of organic dielectric layers 532 and a plurality of vias 533 coupling adjacent metal layers 534 of the plurality of metal layers 534 through the first plurality of organic dielectric layers 532. In some aspects, the first metallization structure 530 may comprise fiberglass impregnated with resin (prepreg), Ajinomoto build-up film (ABF), a resin coated copper (RCC) build-up film or any organic similar material.

In some aspects, the second metallization structure 550 includes a second plurality of inorganic dielectric layers 552, a plurality of metal layers 554 disposed in the second plurality of inorganic dielectric layers 552 and a plurality of vias 553 coupling adjacent metal layers 554 of the plurality of metal layers 554 through the second plurality of inorganic dielectric layers 552. In some aspects, the second metallization structure 550 may comprise multiple layers of silicon or other inorganic based build-up layers as part of a copper (Cu) damascene process.

A plurality of through-substrate vias (TSVs) 545 are configured to electrically couple the first metallization structure 530 to the second metallization structure 550. The plurality of TSVs 545 traverses the fill material 540 and structure wafer 510 and are disposed outside the first die 520. A plurality of package connectors 535 (e.g., solder bumps, BGA, copper pillar bumps, pins or any suitable connector technology) may be configured to electrically couple the apparatus 500 to an external component, such as a circuit board.

In some aspects, the metal layers and vias of the first metallization structure 530, the second metallization structure 550 and TSVs 545 may comprise any high conductive material, such as, copper (Cu), aluminum (AL), silver (Ag), gold (Au) titanium (Ti), nickel (Ni), tin (Sn), lead (Pb), alloys or combinations thereof.

It will be appreciated that the illustrated configurations and descriptions provided herein are merely to aid in the explanation of the various aspects disclosed herein. Accordingly, the forgoing illustrative examples should not be construed to limit the various aspects disclosed and claimed herein.

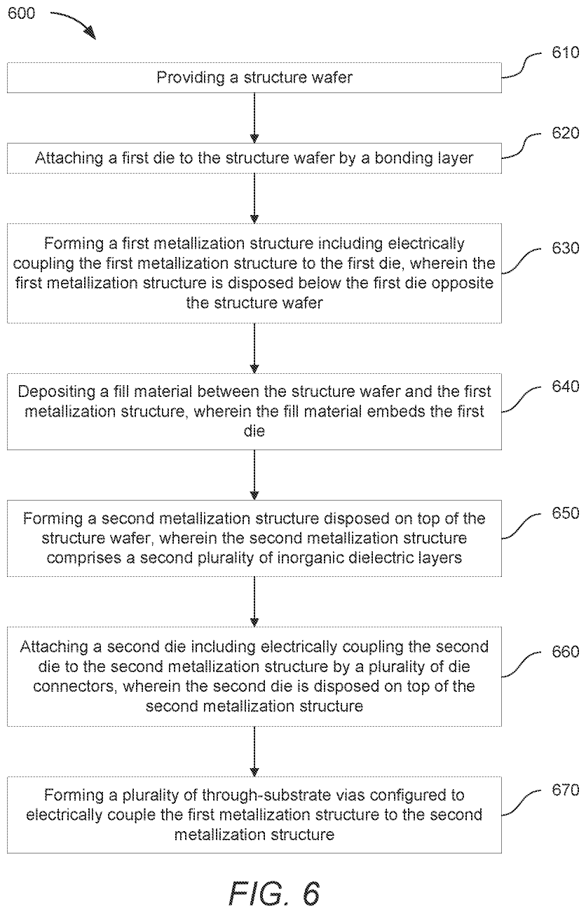

FIG. 6 illustrates a process 600 for manufacturing/fabricating an apparatus with stacked die structure structures (such as an IC package incorporating the features of any of the example apparatuses 100, 200, 300, 400, 500), according to aspects of the disclosure. In some aspects, FIGS. 2A-2I may depict the substrate at different stages of manufacturing according to the process 600. It will be appreciated from the foregoing that there are various methods for fabricating devices including a plurality of buried bump structures as disclosed herein.

At operation 610, the process 600 includes providing a structure wafer (e.g., structure wafer 110, 210, 310, 410 or 510).

At operation 620, the process 600 includes attaching a first die (e.g., first die 120, 220, 320, 420 or 520) to the structure wafer (e.g., structure wafer 110, 210, 310, 410 or 510) by a bonding layer (e.g., bonding layer 115, 215, 315, 415 or 515).

At operation 630, the process 600 includes forming a first metallization structure (e.g., first metallization structure 130, 230, 330, 430 or 530) including electrically coupling the first metallization structure (e.g., first metallization structure 130, 230, 330, 430 or 530) to the first die (e.g., first die 120, 220, 320, 420 or 520), wherein the first metallization structure is disposed below the first die opposite the structure wafer (e.g., structure wafer 110, 210, 310, 410 or 510).

At operation 640, the process 600 includes depositing a fill material (e.g., fill material 140, 240, 340, 440 or 540) between the structure wafer (e.g., structure wafer 110, 210, 310, 410 or 510) and the first metallization structure (e.g., first metallization structure 130, 230, 330, 430 or 530), wherein the fill material (e.g., fill material 140, 240, 340, 440 or 540) embeds the first die (e.g., first die 120, 220, 320, 420 or 520).

At operation 650, the process 600 includes forming a second metallization structure (e.g., second metallization structure 150, 250, 350, 450 or 550) disposed on top of the structure wafer (e.g., structure wafer 110, 210, 310, 410 or 510), wherein the second metallization structure (e.g., second metallization structure 150, 250, 350, 450 or 550) comprises a second plurality of inorganic dielectric layers (e.g., inorganic dielectric layers 152, 252, 352, 452 or 552).

At operation 660, the process 600 includes attaching a second die (e.g., second die 160, 260, 360, 460 or 560) including electrically coupling the second die (e.g., second die 160, 260, 360, 460 or 560) to the second metallization structure (e.g., second metallization structure 150, 250, 350, 450 or 550) by a plurality of die connectors (e.g., die connectors 165, 265, 365, 465 or 565), wherein the second die (e.g., second die 160, 260, 360, 460 or 560) is disposed on top of the second metallization structure (e.g., second metallization structure 150, 250, 350, 450 or 550).

At operation 670, the process 600 includes forming a plurality of through-substrate vias (e.g., through-substrate vias 145, 245, 345, 445 or 545) configured to electrically couple the first metallization structure (e.g., first metallization structure 130, 230, 330, 430 or 530) to the second metallization structure e.g., second metallization structure 150, 250, 350, 450 or 550).

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

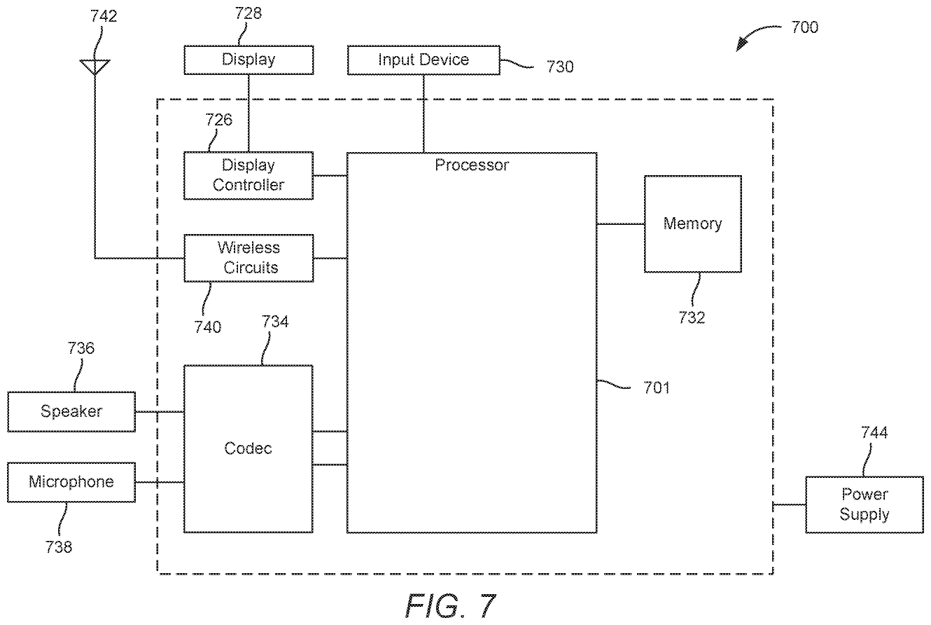

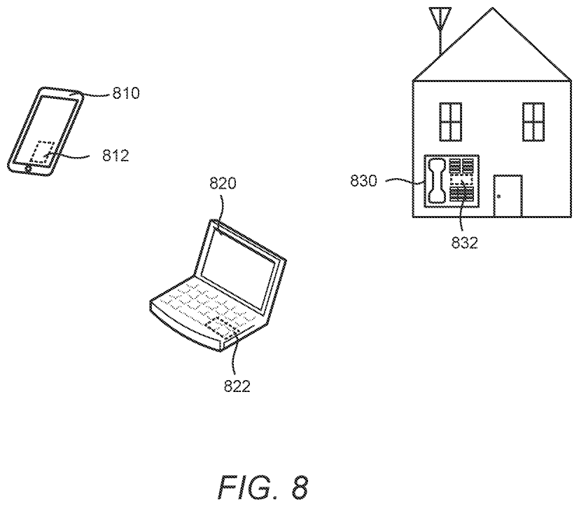

FIG. 7 illustrates a mobile device 700, according to aspects of the disclosure. In some aspects, the mobile device 700 may be implemented by including one or more IC devices including the stacked die structures as disclosed herein.

In some aspects, mobile device 700 may be configured as a wireless communication device. As shown, mobile device 700 includes processor 701. Processor 701 may be communicatively coupled to memory 732 over a link, which may be a die-to-die or chip-to-chip link. Mobile device 700 also includes display 728 and display controller 726, with display controller 726 coupled to processor 701 and to display 728. The mobile device 700 may include input device 730 (e.g., physical, or virtual keyboard), power supply 744 (e.g., battery), speaker 736, microphone 738, and wireless antenna 742. In some aspects, the power supply 744 may directly or indirectly provide the supply voltage for operating some or all of the components of the mobile device 700.

In some aspects, FIG. 7 may include coder/decoder (CODEC) 734 (e.g., an audio and/or voice CODEC) coupled to processor 701; speaker 736 and microphone 738 coupled to CODEC 734; and wireless circuits 740 (which may include a modem, RF circuitry, filters, etc.) coupled to wireless antenna 742 and to processor 701.

In some aspects, one or more of processor 701 (e.g., SoCs, application processor (AP), central processing unit (CPU), digital signal processor (DSP), etc.), display controller 726, memory 732, CODEC 734, and wireless circuits 740 (e.g., baseband interface) including IC devices that are packaged as IC packages and including stacked die structures according to the various aspects described in this disclosure.

It should be noted that although FIG. 7 depicts a mobile device 700, similar architecture may be used to implement an apparatus including, a microprocessor, a server, a set top box, a music player, a video player, an entertainment unit, a navigation device, a personal digital assistant (PDA), a fixed location data unit, a computer, a laptop, a tablet, a communications device, a mobile phone, or other similar devices.

FIG. 8 illustrates various electronic devices 810, 820, and 830 that may incorporate IC devices 812, 822, and 832, which may be packaged as IC packages having stacked die structures as disclosed herein, according to aspects of the disclosure.

For example, a mobile phone device 810, a laptop computer device 820, and a fixed location terminal device 830 may each be considered generally user equipment (UE) and may include one or more IC devices, such as IC devices 812, 822, and 832, and a power supply to provide the supply voltages to power the IC devices. The IC devices 812, 822, and 832 may, for example, correspond to an IC device package having stacked die structures as described herein.

The devices 810, 820, and 830 illustrated in FIG. 8 are merely non-limiting examples. Other electronic devices may also feature the IC devices including stacked die structure as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1, 2A-2I, and 3-8 may be rearranged and/or combined into a single component, process, feature, or function or incorporated in several components, processes, or functions. Additional elements, components, processes, and/or functions may also be added without departing from the disclosure. In some implementations, FIGS. 1, 2A-2I, and 3-8 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:
Clause 1. An apparatus, comprising: a structure wafer; a first die bonded to the structure wafer by a bonding layer; a first metallization structure disposed below and electrically coupled to the first die opposite the structure wafer; fill material disposed between the structure wafer and the first metallization structure, wherein the fill material embeds the first die; a second metallization structure disposed on top of the structure wafer, wherein the second metallization structure comprises a second plurality of inorganic dielectric layers; a second die disposed on top of the second metallization structure and electrically coupled to the second metallization structure by a plurality of die connectors; and a plurality of through-substrate vias configured to electrically couple the first metallization structure to the second metallization structure.
Clause 2. The apparatus of clause 1, wherein the plurality of die connectors comprises solder balls.
Clause 3. The apparatus of any of clauses 1 to 2, wherein the plurality of die connectors comprises hybrid bonded contacts.
Clause 4. The apparatus of any of clauses 1 to 3, wherein the plurality of through-substrate vias is disposed outside the first die and traverses the fill material and the structure wafer.
Clause 5. The apparatus of any of clauses 1 to 4, wherein the first metallization structure further comprises: a first plurality of dielectric layers; a first plurality of metal layers disposed in the first plurality of dielectric layers; and a first plurality of vias configured to couple adjacent metal layers of the first plurality of metal layers through the first plurality of dielectric layers.
Clause 6. The apparatus of clause 5, wherein the first plurality of dielectric layers comprises: inorganic dielectric layers.
Clause 7. The apparatus of clause 6, wherein the first plurality of dielectric layers comprises: silicon (Si), gallium arsenide (GaAs), or silicon germanium (SiGe).
Clause 8. The apparatus of any of clauses 5 to 7, wherein the first plurality of dielectric layers comprises: organic dielectric layers.
Clause 9. The apparatus of clause 8, wherein the first plurality of dielectric layers comprises: fiberglass impregnated with resin (prepreg), Ajinomoto build-up film (ABF), or a resin coated copper (RCC) build-up film.
Clause 10. The apparatus of any of clauses 1 to 9, wherein the second metallization structure further comprises: a second plurality of metal layers disposed in the second plurality of inorganic dielectric layers; and a second plurality of vias configured to couple adjacent metal layers of the second plurality of metal layers through the second plurality of inorganic dielectric layers.
Clause 11. The apparatus of clause 10, wherein the second plurality of inorganic dielectric layers comprise silicon (Si), gallium arsenide (GaAs), or silicon germanium (SiGe).
Clause 12. The apparatus of any of clauses 1 to 11, wherein at least one of the first metallization structure or the second metallization structure further comprises: one or more integrated passive devices.
Clause 13. The apparatus of clause 12, wherein the one or more integrated passive devices comprises: one or more capacitors; one or more inductors; or combinations thereof.
Clause 14. The apparatus of any of clauses 1 to 13, further comprising: a die underfill disposed between the second die and the second metallization structure, wherein the die underfill and the fill material each comprise an organic material.
Clause 15. The apparatus of any of clauses 1 to 14, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
Clause 16. A method of manufacturing an apparatus, the method comprising: providing a structure wafer; attaching a first die to the structure wafer by a bonding layer; forming a first metallization structure including electrically coupling the first metallization structure to the first die, wherein the first metallization structure is disposed below the first die opposite the structure wafer; depositing a fill material between the structure wafer and the first metallization structure, wherein the fill material embeds the first die; forming a second metallization structure disposed on top of the structure wafer, wherein the second metallization structure comprises a second plurality of inorganic dielectric layers; attaching a second die including electrically coupling the second die to the second metallization structure by a plurality of die connectors, wherein the second die is disposed on top of the second metallization structure; and forming a plurality of through-substrate vias configured to electrically couple the first metallization structure to the second metallization structure.
Clause 17. The method of clause 16, wherein forming the first metallization structure further comprises: forming a first plurality of dielectric layers; forming a first plurality of metal layers disposed in the first plurality of dielectric layers; and forming a first plurality of vias configured to couple adjacent metal layers of the first plurality of metal layers through the first plurality of dielectric layers.
Clause 18. The method of clause 17, wherein the first plurality of dielectric layers comprises inorganic dielectric layers and forming the first metallization structure comprises a copper damascene process.
Clause 19. The method of any of clauses 16 to 18, wherein forming the second metallization structure further comprises: forming a second plurality of metal layers disposed in the second plurality of inorganic dielectric layers; and forming a second plurality of vias configured to couple adjacent metal layers of the second plurality of metal layers through the second plurality of inorganic dielectric layers.
Clause 20. The method of clause 19, wherein forming the second metallization structure comprises a copper damascene process.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An apparatus, comprising:
a structure wafer;
a first die bonded to the structure wafer by a bonding layer;
a first metallization structure disposed below and electrically coupled to the first die opposite the structure wafer;
fill material disposed between the structure wafer and the first metallization structure, wherein the fill material embeds the first die;
a second metallization structure disposed on top of the structure wafer, wherein the second metallization structure comprises a second plurality of inorganic dielectric layers;
a second die disposed on top of the second metallization structure and electrically coupled to the second metallization structure by a plurality of die connectors; and
a plurality of through-substrate vias configured to electrically couple the first metallization structure to the second metallization structure.

2. The apparatus of claim 1, wherein the plurality of die connectors comprises solder balls.

3. The apparatus of claim 1, wherein the plurality of die connectors comprises hybrid bonded contacts.

4. The apparatus of claim 1, wherein the plurality of through-substrate vias is disposed outside the first die and traverses the fill material and the structure wafer.

5. The apparatus of claim 1, wherein the first metallization structure further comprises:
a first plurality of dielectric layers;
a first plurality of metal layers disposed in the first plurality of dielectric layers; and
a first plurality of vias configured to couple adjacent metal layers of the first plurality of metal layers through the first plurality of dielectric layers.

6. The apparatus of claim 5, wherein the first plurality of dielectric layers comprises:
inorganic dielectric layers (132).

7. The apparatus of claim 6, wherein the first plurality of dielectric layers comprises:
silicon (Si), gallium arsenide (GaAs), or silicon germanium (SiGe).

8. The apparatus of claim 5, wherein the first plurality of dielectric layers comprises:
organic dielectric layers (532).

9. The apparatus of claim 8, wherein the first plurality of dielectric layers comprises:
fiberglass impregnated with resin (prepreg), Ajinomoto build-up film (ABF), or a resin coated copper (RCC) build-up film.

10. The apparatus of claim 1, wherein the second metallization structure further comprises:
a second plurality of metal layers disposed in the second plurality of inorganic dielectric layers; and
a second plurality of vias configured to couple adjacent metal layers of the second plurality of metal layers through the second plurality of inorganic dielectric layers.

11. The apparatus of claim 10, wherein the second plurality of inorganic dielectric layers comprise silicon (Si), gallium arsenide (GaAs), or silicon germanium (SiGe).

12. The apparatus of claim 1, wherein at least one of the first metallization structure or the second metallization structure further comprises:
one or more integrated passive devices.

13. The apparatus of claim 12, wherein the one or more integrated passive devices comprises:
one or more capacitors;
one or more inductors; or
combinations thereof.

14. The apparatus of claim 1, further comprising:
a die underfill disposed between the second die and the second metallization structure, wherein the die underfill and the fill material each comprise an organic material.

15. The apparatus of claim 1, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

16. A method of manufacturing an apparatus, the method comprising:
providing a structure wafer;
attaching a first die to the structure wafer by a bonding layer;
forming a first metallization structure including electrically coupling the first metallization structure to the first die, wherein the first metallization structure is disposed below the first die opposite the structure wafer;
depositing a fill material between the structure wafer and the first metallization structure, wherein the fill material embeds the first die;
forming a second metallization structure disposed on top of the structure wafer, wherein the second metallization structure comprises a second plurality of inorganic dielectric layers;
attaching a second die including electrically coupling the second die to the second metallization structure by a plurality of die connectors, wherein the second die is disposed on top of the second metallization structure; and
forming a plurality of through-substrate vias configured to electrically couple the first metallization structure to the second metallization structure.

17. The method of claim 16, wherein forming the first metallization structure further comprises:
forming a first plurality of dielectric layers;
forming a first plurality of metal layers disposed in the first plurality of dielectric layers; and
forming a first plurality of vias configured to couple adjacent metal layers of the first plurality of metal layers through the first plurality of dielectric layers.

18. The method of claim 17, wherein the first plurality of dielectric layers comprises inorganic dielectric layers and forming the first metallization structure comprises a copper damascene process.

19. The method of claim 16, wherein forming the second metallization structure further comprises:
forming a second plurality of metal layers disposed in the second plurality of inorganic dielectric layers; and
forming a second plurality of vias configured to couple adjacent metal layers of the second plurality of metal layers through the second plurality of inorganic dielectric layers.

20. The method of claim 19, wherein forming the second metallization structure comprises a copper damascene process.
